(19) United States
(12) Patent Application Publication
(10) Pub. No.: US 2026/0157183 A1
(43) Pub. Date: Jun. 4, 2026

(54) SEMICONDUCTOR CHIP PACKAGE WITH AN INTEGRATED COLD PLATE

(71) Applicant: Avago Technologies International Sales Pte. Limited, Singapore (SG)

(72) Inventors: Sam Ziqun Zhao, Irvine, CA (US); David K. Hollis, San Jose, CA (US); Greg Barsky, San Jose, CA (US); Reza Sharifi, Irvine, CA (US); Sampath K. Karikalan, Irvine, CA (US)

(21) Appl. No.: 19/403,496

(22) Filed: Nov. 28, 2025

Related U.S. Application Data
(60) Provisional application No. 63/726,456, filed on Nov. 29, 2024.

(51) Int. Cl. H01L 23/427; H01L 23/00; H01L 23/10; H01L 23/538; H01L 25/065

(52) U.S. Cl. CPC H10W 40/73; H10W 76/60; H10W 70/611; H10W 90/00; H10W 90/401; H10W 90/734

(57) ABSTRACT

A semiconductor package includes an integrated cold plate (ICP) lid that is mounted above semiconductor chips that are heat sources and are interfaced with the semiconductor chips through a thermal interface layer. The ICP lid includes an inlet through which cooling fluid is to be supplied, an outlet through which the cooling fluid is to be discharged, and a fluid communication path between the inlet and the outlet. The cooling fluid travels from the inlet to the outlet through one or more channels formed in the ICP lid interior, or through a plurality of heat transfer fins arranged in a cavity formed in the ICP lid interior. By providing an ICP lid with a cooling fluid inlet and outlet, heat dissipation can be performed close to the semiconductor chips while providing a pressure release path during high temperature testing or solder reflow process.

### CROSS-REFERENCE TO RELATED APPLICATION(S)

This application claims the benefit of U.S. Provisional Application No. 63/726,456, filed on Nov. 29, 2024, which is incorporated by reference herein.

### BACKGROUND

Power consumption of semiconductor chips is increasing at an unprecedented rate, especially when they are used for artificial intelligence and machine learning applications and high-performance computing. Today's chips used for such applications, e.g., graphics processing units (GPUs), each consume more than 1000 watts, and that number is expected to rise to about 2000 watts in a year and 3000 watts or more in two years. Because a large number of these chips are mounted in close proximity to each other, e.g., 72 GPUs in a single rack, heat dissipation has become a major concern. Without proper heat dissipation, the operating temperature of the chips will rise, and this will cause the chips to demand more power. When additional power is supplied, the temperature will rise even higher and a phenomena known as thermal runway might occur.

U.S. Patent Application Publication No. 2023/0386960 discloses a semiconductor package in which a metal lid is integrated with sealed heat pipes to enhance heat removal from the semiconductor die. The heat pipes are embedded within the lid so that working fluid inside each pipe transfers heat away from localized hot spots toward cooler peripheral regions of the lid, thereby equalizing temperature distribution and lowering junction temperature. This can be coupled to external cooling components such as cold plates or vapor chambers to enable high-capacity heat dissipation without increasing package footprint.

### SUMMARY

One or more embodiments provide a semiconductor package having an integrated cold plate (ICP) lid mounted above semiconductor chips that are heat sources and are interfaced with the semiconductor chips through a thermal interface layer. The ICP lid includes an inlet through which cooling fluid is to be supplied, an outlet through which the cooling fluid is to be discharged, and a fluid communication path between the inlet and the outlet. In one embodiment, the cooling fluid travels from the inlet to the outlet through one or more channels that are formed within the interior of the ICP lid. In another embodiment, the cooling fluid travels from the inlet to the outlet through a plurality of heat transfer fins formed in a cavity that is at the interior of the ICP lid and communicates with the inlet and the outlet. By providing an ICP lid with an inlet and an outlet through which cooling fluid can be pumped when needed, heat dissipation can be performed much closer to the semiconductor chips and thus more efficiently than in the case of an external cold plate that is used conventionally. In addition, when residual cooling fluid remaining inside the lid vaporizes during high temperature testing or solder reflow process, the vaporized cooling fluid can easily escape through the inlet and the outlet, thereby preventing internal pressure build-up within the lid. In contrast, in semiconductor packages employing metal lids integrated with sealed heat pipes, vaporized cooling fluid may cause internal pressure to rise, potentially resulting in swelling, deformation, or other reliability issues in the lid structure.

### BRIEF DESCRIPTION OF THE DRAWINGS

FIG. 1 illustrates a semiconductor package of a first type having an ICP lid.

FIG. 2 illustrates a semiconductor package of a second type having an ICP lid.

FIGS. 3A-3B illustrate one example of an ICP lid having microchannels formed in a serpentine pattern.

FIGS. 4A-4B illustrate another example of an ICP lid having microchannels formed in a serpentine pattern.

FIG. 5 illustrates a semiconductor package having an ICP lid with an inlet and an outlet for a cooling liquid, where the inlet and the outlet are arranged on a side surface of the ICP lid.

FIG. 6 illustrates a semiconductor package having an ICP lid with an inlet and an outlet for a cooling liquid, where the inlet and the outlet are configured as male connectors for connection with an external cooling liquid supply.

FIG. 7 illustrates a semiconductor package having an ICP lid with an inlet, an outlet, and a cavity in communication with the inlet and the outlet and in which cooling fins are provided.

FIGS. 8A-8C each illustrate a two-piece structure for an ICP lid.

FIG. 9 illustrates a plurality of semiconductor packages each having an ICP lid and an external cold plate interfaced with each of the ICP lids of the semiconductor packages.

FIG. 10A is a perspective view of an ICP lid according to embodiments with an integrated manifold.

FIG. 10B is a transparent view of the integrated manifold in FIG. 10A that shows the interior of the ICP lid.

FIG. 10C is a perspective view of the ICP lid of FIG. 10A with the integrated manifold removed.

FIG. 10D illustrates a cross-section of the ICP lid taken along line 10D-10D in FIG. 10C.

FIG. 10E is a perspective view of a cross-section of the ICP lid.

FIG. 10F illustrates a cross-section taken along line 10F-10F in FIG. 10E of fins that are arranged in the ICP lid.

### DETAILED DESCRIPTION

In the description below, spatially relative terms, such as “beneath,” “below,” “lower,” “above,” “upper” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, for clarity, identical reference numbers have been used, where applicable, to designate identical elements that are common between figures. It is also contemplated that features of one embodiment may be incorporated in other embodiments without further recitation.

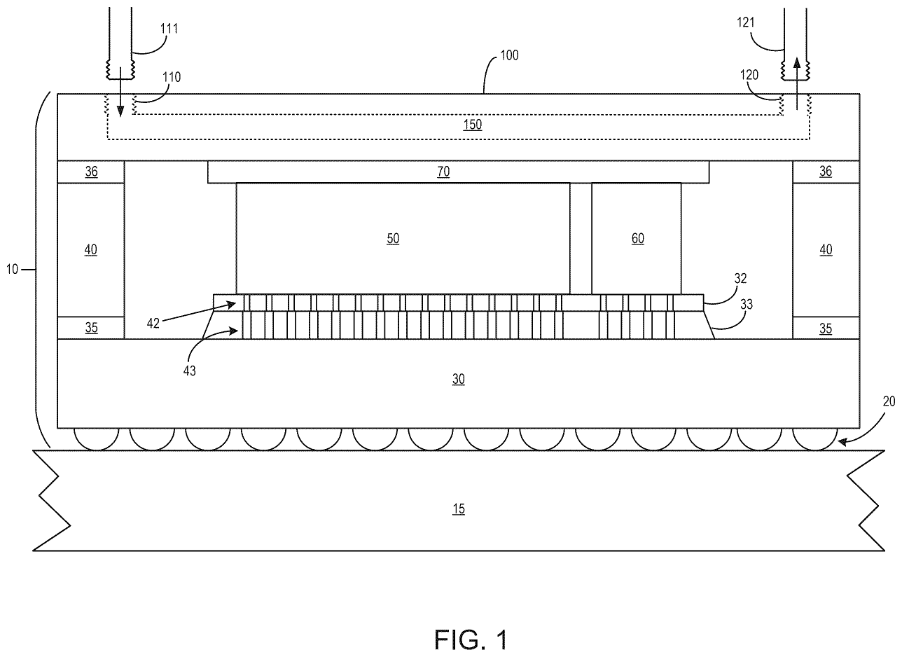

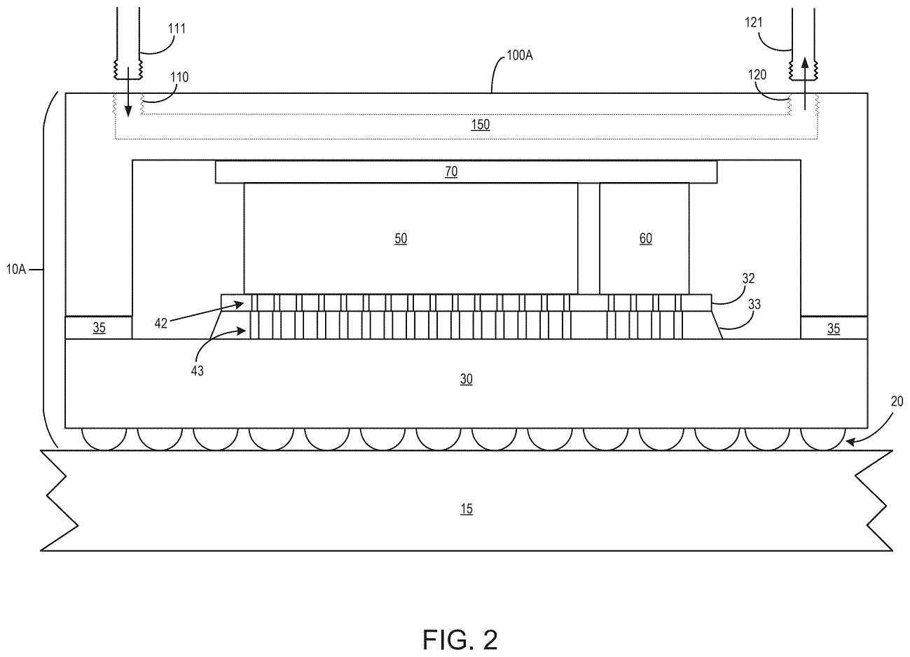

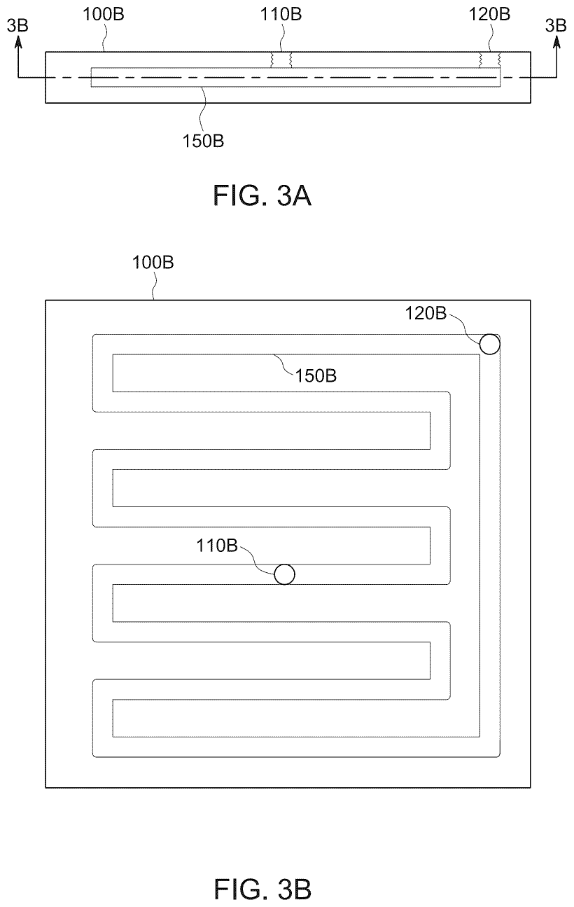

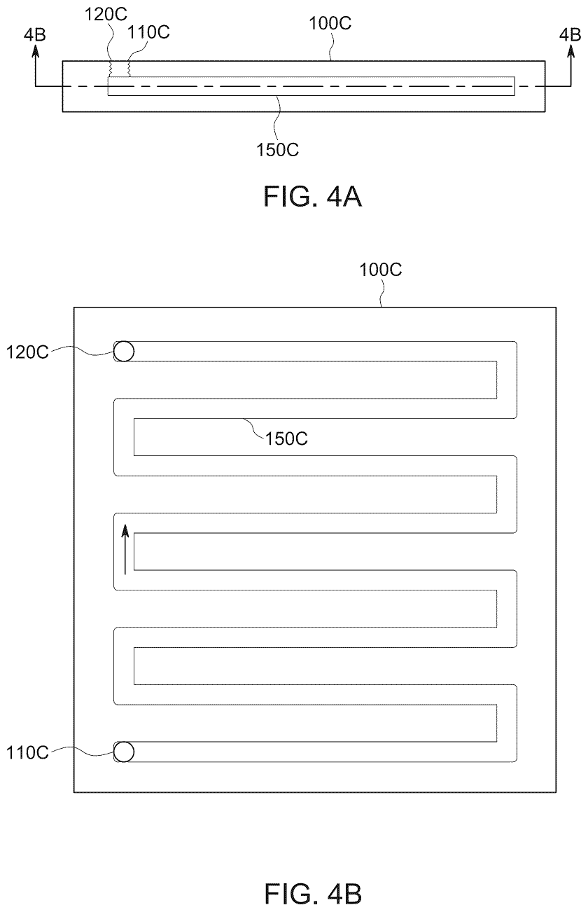

FIGS. 1 and 2 are schematic cross-sectional views of a semiconductor package of two different types, each having an integrated cold plate (ICP) lid according to embodiments. FIG. 1 illustrates a semiconductor package 10 with an ICP lid 100 and a stiffener ring 40, which is bonded to ICP lid 100, whereas FIG. 2 illustrates a semiconductor package 10A with an ICP lid 100A in which the stiffener ring structure is formed integrally with the ICP lid structure. In general, both of the semiconductor packages depicted in FIGS. 1 and 2 have a chip-on-wafer-on-substrate (COWOS) structure. In addition, all of the semiconductor packages illustrated herein and the ICP lids of these semiconductor packages have a rectangular shape when viewed from the top or bottom. The rectangular shape is illustrated in FIGS. 3B and 4B.

As shown in FIG. 1, semiconductor package 10 further includes a package substrate 30 on which a plurality of semiconductor dies 50, 60 are mounted. Semiconductor dies 50 are, for example, high-bandwidth memory (HBM) chips that are stacked on top of each other, and semiconductor die 60 is, for example, an XPU chip, which may be a CPU (central processing unit), GPU (graphics processing unit), TPU (tensor processing unit), NPU (neural processing unit), or VPU (vision processing unit). They are electrically connected to a wiring layer on package substrate 30 through a plurality of through-silicon vias (TSVs) 42 formed in a silicon interposer layer 32 and a plurality of contacts 43 formed in an insulating layer 33. Stiffener ring 40 surrounds semiconductor dies 50, 60 and is bonded to package substrate 30 via an adhesive material 35 and to ICP lid 100 via an adhesive material 36. In addition, a thermal interface material (TIM) layer 70 is interposed between, and in direct contact with, ICP lid 100 and semiconductor dies 50, 60. During operation, heat generated by semiconductor dies 50, 60 is conducted to ICP lid 100 through TIM layer 70. Example materials for TIM layer 70 include polycrystalline diamond, graphene, graphite, silicon carbide (SiC), titanium carbide (TiC), tungsten carbide (WC), boron carbide (B₄C), metallic nitrides (TiN, ZrN, etc.), molybdenum disulfide (MoS₂), copper-graphene composite, sintered silver, indium solder, gold-tin solder, silicone-based grease filled with silver, aluminum oxide, zinc oxide, boron nitride, and polymer-based phase-change materials. TIM layer 70 can be a single homogeneous layer of TIM material. TIM layer 70 may also be a composite of sublayers of materials designed to minimize thermal contact resistances between the metal lid and the silicon dies. In one embodiment, TIM layer 70 is formed by sequentially stacking from the side of semiconductor dies 50, 60, layers of polycrystalline diamond, titanium or tungsten carbide, solder, gold, and nickel.

In the example shown in FIG. 1, semiconductor package 10 is mounted on a printed circuit board (PCB) 15. Specifically, a ball grid array (BGA) 20, which is formed on a bottom surface of package substrate 30, is joined to wiring pads formed on an upper surface of PCB 15.

The ICP according to embodiments includes an inlet 110 and an outlet 120, and a fluid communication path between inlet 110 and outlet 120. Inlet 110 is connected to a cooling liquid supply 111 and outlet 120 is connected cooling liquid return 121. During operation, cooling liquid supplied through inlet 110 absorbs the heat generated by semiconductor dies 50, 60 and conducted to ICP lid 100 through TIM layer 70, and the cooling liquid that absorbed the heat is discharged through outlet 120.

The fluid communication path between inlet 110 and outlet 120 may be implemented as one or more microchannels with various designs. In addition, the cross-section of the microchannels may be of any shape, including circular, elliptical, rectangular, triangular, and irregular. The size of the microchannels may be 20-80 percent of the thickness of the ICP lid. The microchannels may be laid out in a plane parallel to the planar surfaces of the ICP lid according to any pattern, e.g., zigzag or serpentine. The pattern selected may concentrate the microchannels in areas that are directly above high heat generating zones, e.g., directly above semiconductor die 60 implemented as a GPU chip. In FIG. 1, a single inlet 110, a single outlet 120, and a single microchannel 150 are depicted for simplicity. However, one or more microchannels may be formed, and one or more inlets and one or more outlets may be provided.

The ICP lid of semiconductor package 10A, i.e., ICP lid 100A, differs from that of semiconductor package 10 in that the stiffener ring structure is formed integrally with the ICP lid structure. Thus, ICP lid 100A is described hereafter as including the stiffener ring that surrounds semiconductor dies 50, 60. In this structure, the stiffener ring section of ICP lid 100A is bonded to package substrate 30 via adhesive material 35. All other structure of semiconductor package 10A is the same as that of semiconductor package 10.

FIGS. 3A and 3B illustrate ICP lid 100B having microchannels formed in a serpentine pattern. FIG. 3A is a cross-sectional side view and FIG. 3B illustrates a cross-section that is taken along line 3B-3B in FIG. 3A. FIG. 3B illustrates the serpentine pattern of microchannel 150B and locations of inlet 110B and outlet 120B. The ICP lid structure of ICP lid 100A may also have the configuration of inlet 110B, outlet 120B, and microchannel 150B illustrated in FIGS. 3A and 3B.

FIGS. 4A and 4B illustrate ICP lid 100C having microchannels formed in a serpentine pattern. ICP lid 100C differs from ICP lid 100B in the locations of the inlet and the outlet. FIG. 4A is a cross-sectional side view and FIG. 4B illustrates a cross-section that is taken along line 4B-4B in FIG. 4A. FIG. 4B illustrates the serpentine pattern of microchannel 150C and locations of inlet 110C and outlet 120C. The ICP lid structure of ICP lid 100A may also have the configuration of inlet 110C, outlet 120C, and microchannel 150C illustrated in FIGS. 4A and 4B.

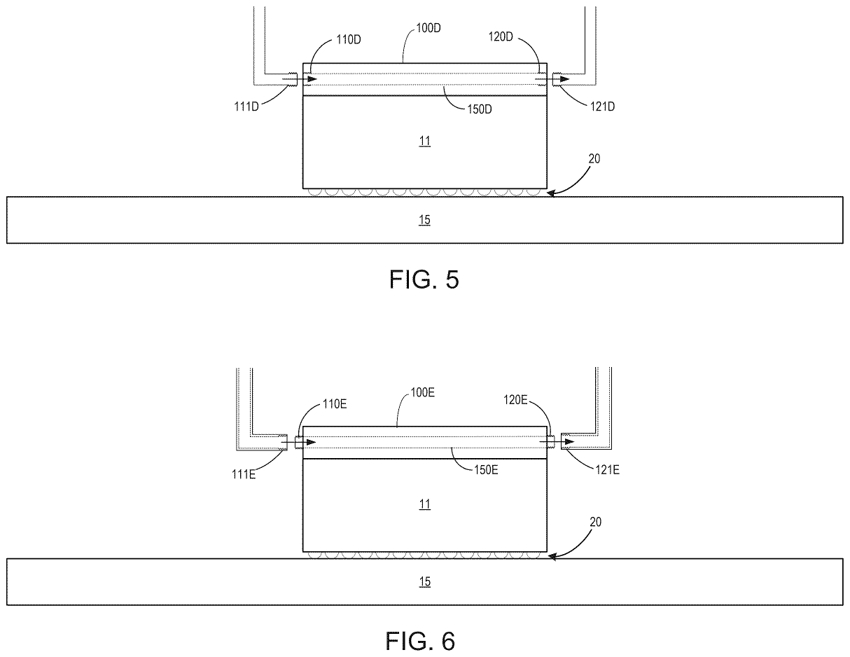

FIG. 5 illustrates a semiconductor package with an ICP lid 100D. Package body 11 depicted in FIG. 5 represents semiconductor package 10 of FIG. 1 without ICP lid 100. Therefore, the semiconductor package of FIG. 5 is identical to that of FIG. 1 except ICP lid 100D replaces ICP lid 100. ICP lid 100D differs from ICP lid 100 in that its inlet 110D and its outlet 120D are arranged on a side surface of ICP lid 100D. To accommodate this configuration, cooling liquid supply 111D and cooling liquid return 121D have horizontal sections, instead of vertical sections, that engage with inlet 110D and outlet 120D.

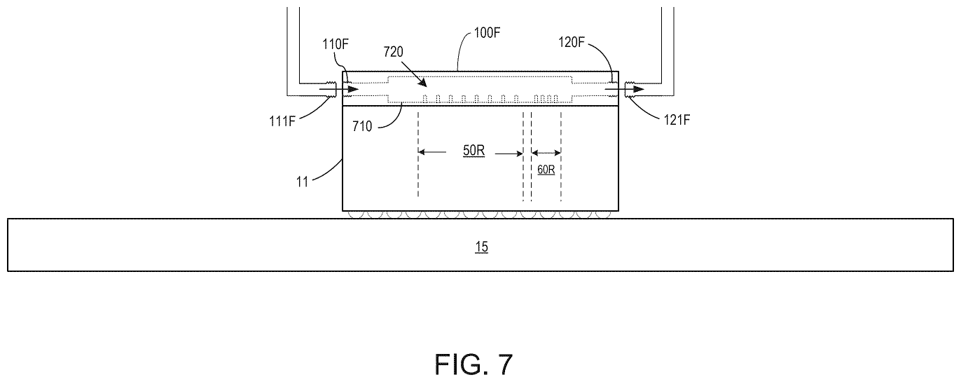

FIG. 6 illustrates a semiconductor package with an ICP lid 100E. Package body 11 depicted in FIG. 6 represents semiconductor package 10 of FIG. 1 without ICP lid 100. Therefore, the semiconductor package of FIG. 6 is identical to that of FIG. 1 except ICP lid 100E replaces ICP lid 100. ICP lid 100E differs from ICP lid 100 in that its inlet 110E and its outlet 120E are configured as male connectors. By contrast, inlet 110 and outlet 120 are configured as female connectors. To accommodate this configuration of ICP lid 100E, cooling liquid supply 111E and cooling liquid return 121E have respective connective portions with inlet 110E and outlet 120E that are configured as female connectors.

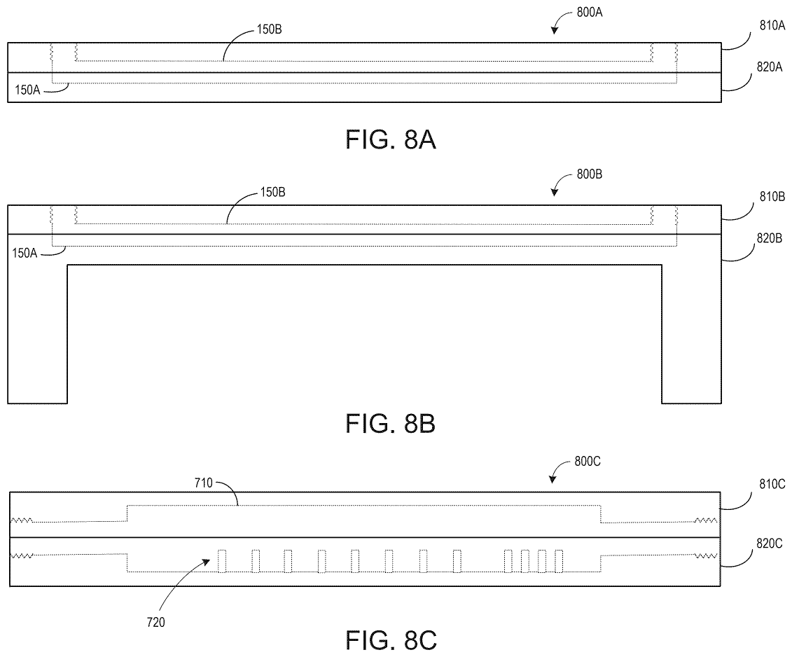

FIG. 7 illustrates a semiconductor package with an ICP lid 100F. Package body 11 depicted in FIG. 7 represents semiconductor package 10 of FIG. 1 without ICP lid 100. Therefore, the semiconductor package of FIG. 7 is identical to that of FIG. 1 except ICP lid 100F replaces ICP lid 100. ICP lid 100F differs from ICP lid 100 in that its inlet 110F and its outlet 120F are arranged on a side surface of ICP lid 100F and the fluid communication path between inlet 110F and outlet 120F include a cavity 710 and a cooling fin structure, e.g., a plurality of fins 720, arranged within cavity 710. The shape of fins 720 may be straight or curved. Fins 720 may be pin fins and arranged in a fanout pattern. In the example shown in FIG. 7, fins 720 are arranged so that its density within cavity 710 above semiconductor die region 50R corresponding to, for example, location of memory chips, is less than its density within the cavity above semiconductor die region 60R corresponding to, for example, location of GPU chip, because the GPU chip generates heat in much higher amounts than the memory chips. In addition, to accommodate locations of inlet 110F and outlet 120F on the side surface of ICP lid 100F, cooling liquid supply 111F and cooling liquid return 121F have horizontal sections that engage with inlet 110F and outlet 120F.

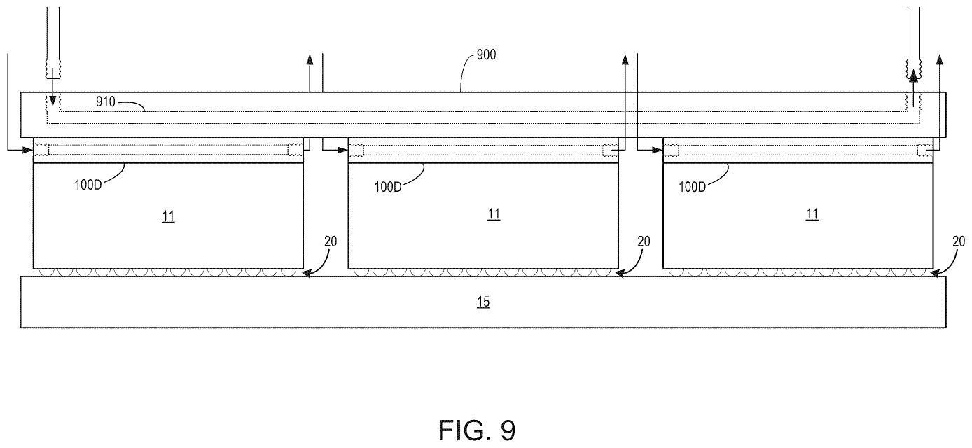

FIGS. 8A-8C each illustrate a two-piece structure for an ICP lid. FIG. 8A illustrates ICP lid 800A that includes an upper lid 810A and a lower lid 820A that are joined together and hermetically sealed by a seal 815A. FIG. 8B illustrates ICP lid 800B that includes an upper lid 810B and a lower lid 820B that are joined together and hermetically sealed by a seal 815B. FIG. 8C illustrates ICP lid 800C that includes an upper lid 810C and a lower lid 820C that are joined together and hermetically sealed by a seal 815C. For the two-piece ICP lids depicted in FIGS. 8A and 8B, which correspond to the ICP lids of FIGS. 1 and 2, respectively, microchannels 850A are patterned and etched into the lower lid (lower lid 820A or lower lid 820B). The top lid may be flat or, as depicted in FIGS. 8A and 8B, the top lid (top lid 810A or top lid 810B) may also be patterned and etched at locations 850B corresponding to microchannels 850A formed in the bottom lid. For the two-piece ICP lids depicted in FIG. 8C, corresponding to the ICP lid of FIG. 7, a cavity 710 is patterned and etched into bottom lid 820C and top lid 810C, and fins 720 are formed on bottom lid 820C by micro-skiving. Each of seals 815A, 815B, 815C is formed along an outer periphery of the corresponding ICP lid. Therefore, seals 815A, 815B, 815C each have a rectangular shape corresponding to the rectangular shape of the ICP lid. Each of seals 815A, 815B, 815C is, for example, an elastomer O-ring, polymer gasket, or a metal gasket, and hermetically seals the interior of the ICP lid from the outside to prevent leaking of cooling liquid to the outside. In addition, each of seals 815A, 815B, 815C is formed of a material capable of maintaining structural integrity under high temperature testing conditions (at 110° C. to 125° C.) or during solder reflow process at approximately 245° C.

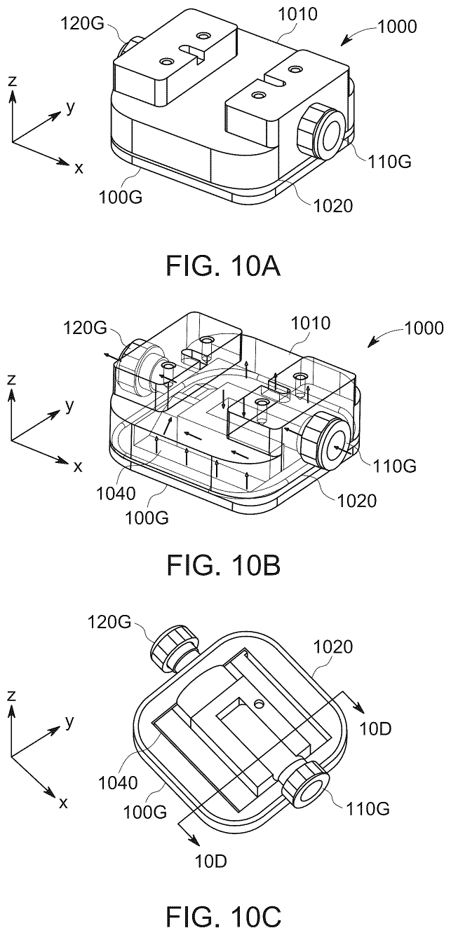

FIG. 9 illustrates a plurality of semiconductor packages each having ICP lid 100D and an external cold plate 900 interfaced with each of ICP lids 100D of the semiconductor packages. Each of the semiconductor packages has a corresponding package body 11 that is mounted to PCB 15 via BGA 20. External cold plate 900 has microchannels 910 formed therein for passing cooling liquid therethrough. Although not illustrated, external cold plate 900 is also mounted to PCB 15 and so the semiconductor packages, each having ICP lid 100D, are sandwiched between external cold plate 900 and PCB 15. In addition, a thermal interface material is provided between external cold plate 900 and each ICP lid 100D.

In the embodiments, the material for the ICP lid is copper, and the material for the external cold plate is also copper. However, other metals with good heat dissipation properties may be used for both the ICP lid and the external cold plate.

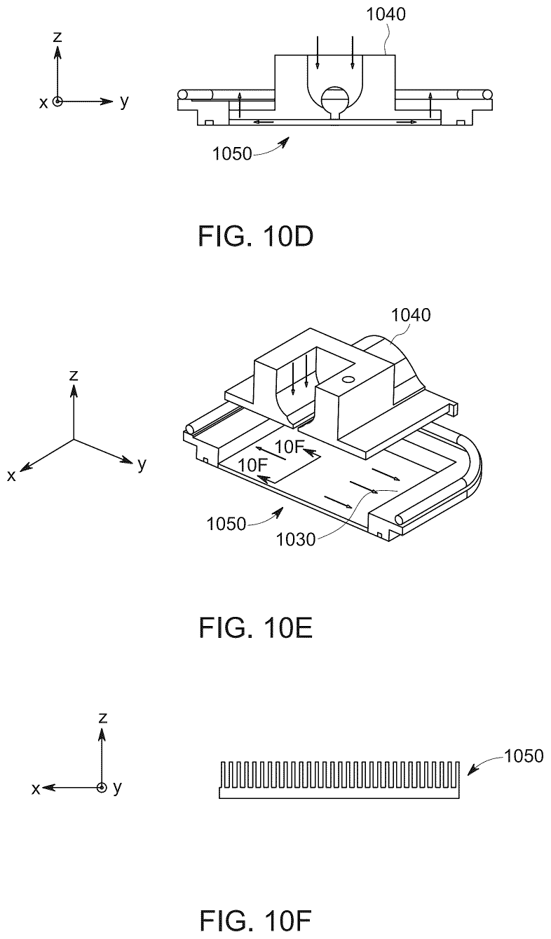

FIG. 10A is a perspective view of an ICP lid 100G with an integrated manifold 1010, also referred to herein as an ICP lid-manifold assembly 1000. ICP lid-manifold assembly 1000 includes a seal 1020 between ICP lid 100G and integrated manifold 1010. Seal 1020 is, for example, an elastomer O-ring, polymer gasket, or a metal gasket, and hermetically seals the interior of ICP lid-manifold assembly 1000 from the outside to prevent leaking of cooling liquid to the outside. In addition, seal 1020 is formed of a material capable of maintaining structural integrity under high temperature testing conditions (at 110° C. to 125° C.) or during solder reflow process at approximately 245° C. Integrated manifold 1010 includes an inlet 110G to which a cooling liquid supply is connected and an outlet 120G to which a cooling liquid return is connected. The direction of the cooling liquid flow through ICP lid-manifold assembly 1000 is shown by arrows depicted in FIG. 10B. Inlet 110G and outlet 120G of ICP lid-manifold assembly 1000 are arranged on the sides of ICP lid-manifold assembly 1000. In some embodiments, the inlet and the outlet of the ICP lid-manifold assembly may be arranged on the top of the ICP lid-manifold assembly.

FIG. 10B is a transparent view of integrated manifold 1010 that shows the interior of ICP lid 100G. The interior of ICP lid 100G includes an impingement-type flow diffuser block 1040. FIG. 10C is a perspective view of ICP lid-manifold assembly 1000 with integrated manifold 1010 removed. FIG. 10D illustrates a cross-section of ICP lid 100G taken along line 10D-10D in FIG. 10C. FIG. 10E is a perspective view of a cross-section of ICP lid 100G. In addition to diffuser block 1040, FIGS. 10D and 10E also show fins 1050 that are arranged in a cavity 1030 of ICP lid 100G. Microchannels for the cooling liquid are formed along the longitudinal direction of fins 1050, i.e., in the y direction. FIG. 10F illustrates a cross-section taken along line 10F-10F in FIG. 10E of fins 1050. In one embodiment, fins 1050 have a height H, a width W=0.1*H, and a pitch equal to 0.2*H. Inlet 110G and outlet 120G are sized to be wider in the x direction than two or more of the microchannels for the cooling liquid that are formed in the y direction.

In the embodiments described above, fins, e.g., fins 720 or fins 1050, are formed by a process known in the art as micro-skiving. Other manufacturing methods that may be used in the embodiments include 3D printing. In addition, the fins may be fabricated from copper or other high-conductivity materials and can vary in density depending on the expected heat generation profile of the underlying dies. In some cases, such as the example shown in FIG. 7, a high-density fin region may be positioned directly above the GPU die, with lower-density fins above memory dies.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements.

When an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements.

When an element is referred to herein as being “mounted” on or “disposed” on another element, it is to be understood that the elements can be directly mounted on or disposed on the other element (without any intervening elements) or have intervening elements present between the elements. In contrast, when an element is referred to as being “directly mounted” on or “directed disposed” on another element, it should be understood that no intervening elements are present between the elements.

The above definitions are intended solely to distinguish between the presence or absence of intervening elements and do not preclude other forms of connection, coupling, bonding, mounting, or disposition consistent with the context.

Although one or more embodiments of the present invention have been described in some detail for clarity of understanding, certain changes may be made within the scope of the claims. Accordingly, the described embodiments are to be considered as illustrative and not restrictive, and the scope of the claims is not to be limited to details given herein but may be modified within the scope and equivalents of the claims. In the claims, elements and steps do not imply any particular order of operation unless explicitly stated in the claims.

What is claimed is:

1. A semiconductor package comprising:
a package substrate having a first surface and a second surface opposite to the first surface;
a semiconductor chip mounted on the first surface of the package substrate;
a thermal interface layer in contact with the semiconductor chip; and
a metal plate having a first surface and a second surface opposite to the first surface and in contact with the thermal interface layer,
wherein the metal plate includes an inlet through which a cooling fluid is to be supplied, an outlet through which the cooling fluid is to be discharged, and a fluid communication path between the inlet and the outlet.

2. The semiconductor package of claim 1, wherein the fluid communication path is completely sealed from an interior of the semiconductor package and completely sealed from an exterior of the semiconductor package except at the inlet and the outlet.

3. The semiconductor package of claim 2, wherein at least one of the inlet and the outlet is formed on a side surface of the metal plate.

4. The semiconductor package of claim 1, wherein
the fluid communication path includes an inlet channel communicating with the inlet and an outlet channel communicating with the outlet, and
the metal plate has formed therein a cavity that communicates with the inlet channel and the outlet channel, and a plurality of fins located within the cavity.

5. The semiconductor package of claim 1, wherein at least one of the inlet and the outlet is formed on the first surface of the metal plate.

6. The semiconductor package of claim 1, further comprising:
a ball grid array on the second surface of the package substrate.

7. The semiconductor package of claim 1, further comprising:
a stiffener ring mounted on the first surface of the package substrate and surrounding the semiconductor chip.

8. The semiconductor package of claim 7, wherein the metal plate is bonded to the stiffener ring.

9. The semiconductor package of claim 7, wherein the metal plate is formed integrally with the stiffener ring.

10. The semiconductor package of claim 1, wherein the metal plate is a copper plate.

11. The semiconductor package of claim 1, wherein at least one of the inlet and the outlet is configured as a female connector for connection with a male connector.

12. The semiconductor package of claim 1, wherein at least one of the inlet and the outlet is configured as a male connector for connection with a female connector.

13. The semiconductor package of claim 1, wherein the metal plate includes a top portion and a bottom portion that is patterned to form the fluid communication pattern between the inlet and the outlet.

14. The semiconductor package of claim 13, wherein the top portion is also patterned to form the fluid communication pattern between the inlet and the outlet.

15. The semiconductor package of claim 13, further comprising a hermetic seal between the top portion and the bottom portion.

16. The semiconductor package of claim 1, wherein the cross-section of the channels has a circular, elliptical, rectangular, triangular, or irregular shape.

17. The semiconductor package of claim 1, wherein the fluid communication path has a serpentine shape.

18. A cooling system for a plurality of semiconductor packages according to claim 1, wherein the semiconductor packages are aligned along a first direction, the cooling system comprising:
an external cold plate extending in the first direction and in contact with the first surfaces of the cooling plates of the semiconductor packages, the external cold plate having an inlet through which a cooling fluid is to be supplied, an outlet through which the cooling fluid is to be discharged, and a fluid communication path between the inlet and the outlet.

19. A semiconductor package comprising:
a package substrate having a first surface and a second surface opposite to the first surface;
a semiconductor chip mounted on the first surface of the package substrate;
a thermal interface layer in contact with the semiconductor chip; and
a lid assembly having a surface in contact with the thermal interface layer,
wherein the lid assembly includes an inlet through which a cooling fluid is to be supplied, an outlet through which the cooling fluid is to be discharged, a fluid communication path between the inlet and the outlet, and a diffuser block disposed in the fluid communication path.

20. The semiconductor package of claim 19, wherein the lid assembly includes a body section having a cavity in which the diffuser block is disposed and in which a plurality of fins are arranged, and a manifold that covers the body section to seal the cavity.

21. The semiconductor package of claim 20, wherein the inlet and the outlet are formed in the manifold, and the fluid communication path extends from the inlet to the outlet through the diffuser block and the fins.

22. The semiconductor package of claim 20, further comprising a hermetic seal between the body section and the manifold.
